(19) United States
(12) Patent Application Publication
(10) Pub. No.: US 2024/0030068 A1
(43) Pub. Date: Jan. 25, 2024

(54) PROCESSING METHOD OF WORKPIECE

(71) Applicant: DISCO CORPORATION, Tokyo (JP)

(72) Inventors: Hiroyuki TAKAHASHI, Tokyo (JP); Yoshiteru NISHIDA, Tokyo (JP); Susumu YOKOO, Tokyo (JP)

(21) Appl. No.: 18/353,222

(22) Filed: Jul. 17, 2023

(30) Foreign Application Priority Data
Jul. 21, 2022 (JP) 2022-116427

(51) Int. Cl. H01L 21/822; H01L 21/683

(52) U.S. Cl. CPC H01L 21/822; H01L 21/6836; H01L 2221/68327; H01L 2221/68381

(57) ABSTRACT

A processing method of a workpiece includes a protective film coating step of coating a front surface of a wafer with a protective film, and partly removing the protective film along planned dividing lines, a dividing step of supplying a first gas in a plasma state to divide the wafer into multiple chips along the planned dividing lines, a hydrophilization step of supplying a second gas in a plasma state to at least any of front surfaces and side surfaces of the chips, an exposed adhesive tape, and an annular frame that have been hydrophobized due to the dividing step to hydrophilize the at least any of the front surfaces and the side surfaces of the chips, the exposed adhesive tape, and the annular frame, and a cleaning step of removing the protective film and cleaning a frame unit by a cleaning liquid after the hydrophilization step.

### BACKGROUND OF THE INVENTION

### Field of the Invention

The present invention relates to a processing method of a workpiece in which a gas in a plasma state is used.

### Description of the Related Art

In a related art, a wafer is coated with a protective film in order to protect devices when the wafer is processed by using a gas in a plasma state, and cleaning is executed by a cleaning liquid to remove the protective film after the processing (for example, refer to Japanese Patent Laid-open No. 2001-127011 and Japanese Patent Laid-open No. 2018-156973).

### SUMMARY OF THE INVENTION

Incidentally, plasma etching is often used in the case of dividing a workpiece into multiple chips, the case of removing processing strain and processing dust that remain in processing grooves that mark out multiple chips, and so forth.

In these cases, depending on the kind of gas used, surface layers of the protective film that protects devices, side surfaces of divided chips, an exposed part of a support component that supports a wafer, and so forth are often modified and hydrophobized. Further, when the protective film is not used, surface layers of front surfaces and side surfaces of the chips and the front surface of the support component are modified and hydrophobized. As a result, when the protective film is removed by a cleaning liquid, there are a problem that it is impossible to sufficiently remove the protective film and a problem that it is impossible to sufficiently clean the chips and the support component by the cleaning liquid.

Thus, an object of the present invention is to provide a processing method of a workpiece that can sufficiently execute removal of a protective film with which a workpiece is coated and cleaning of the workpiece, a support component that supports the workpiece, and an annular frame by a cleaning liquid.

In accordance with an aspect of the present invention, there is provided a processing method of a workpiece by which the workpiece is processed in a frame unit in which the workpiece is supported in an opening of an annular frame through a support component. The processing method of a workpiece includes a protective film coating step of coating a front surface of the workpiece with a protective film, a protective film removal step of partly removing the protective film along planned dividing lines, a dividing step of supplying a first gas in a plasma state to divide the workpiece into a plurality of chips along the planned dividing lines, a hydrophilization step of supplying a second gas in a plasma state to at least any of front surfaces and side surfaces of the chips, the support component exposed, and the annular frame that have been hydrophobized due to the dividing step to hydrophilize the at least any of the front surfaces and the side surfaces of the chips, the support component exposed, and the annular frame, and a cleaning step of removing the protective film and cleaning the frame unit by a cleaning liquid after the hydrophilization step.

In accordance with another aspect of the present invention, there is provided a processing method of a workpiece by which the workpiece is processed in a frame unit in which the workpiece is supported in an opening of an annular frame through a support component. The processing method of a workpiece includes a protective film coating step of coating a front surface of the workpiece with a protective film, a processing groove forming step of forming processing grooves in the workpiece from a front surface along planned dividing lines to divide the workpiece into a plurality of chips, a plasma etching step of supplying a first gas in a plasma state to remove processing strain and processing dust that remain in the processing grooves, a hydrophilization step of supplying a second gas in a plasma state to at least any of front surfaces and side surfaces of the chips, the support component exposed, and the annular frame that have been hydrophobized due to the plasma etching step to hydrophilize the at least any of the front surfaces and the side surfaces of the chips, the support component exposed, and the annular frame, and a cleaning step of removing the protective film and cleaning the frame unit by a cleaning liquid after the hydrophilization step.

According to the present invention, it is possible to sufficiently execute the removal of the protective film with which the workpiece is coated and the cleaning of the workpiece, the support component that supports the workpiece, and the annular frame by the cleaning liquid.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a frame unit in a first embodiment;

FIG. 2 is a schematic sectional view illustrating an etching apparatus in the first embodiment;

FIG. 3A is a sectional view illustrating a protective film coating step of a processing method of a workpiece according to the first embodiment;

FIG. 3B is a sectional view illustrating a protective film removal step of the processing method of a workpiece according to the first embodiment;

FIG. 3C is a sectional view illustrating a dividing step of the processing method of a workpiece according to the first embodiment;

FIG. 3D is a sectional view illustrating a hydrophilization step of the processing method of a workpiece according to the first embodiment;

FIG. 3E is a sectional view illustrating a cleaning step of the processing method of a workpiece according to the first embodiment;

FIG. 4 is a schematic sectional view illustrating an etching apparatus in a second embodiment;

FIG. 5A is a sectional view illustrating a protective film coating step of a processing method of a workpiece according to the second embodiment;

FIG. 5B is a sectional view illustrating a processing groove forming step of the processing method of a workpiece according to the second embodiment;

FIG. 5C is a sectional view illustrating a plasma etching step of the processing method of a workpiece according to the second embodiment;

FIG. 5D is a sectional view illustrating a hydrophilization step of the processing method of a workpiece according to the second embodiment; and

FIG. 5E is a sectional view illustrating a cleaning step of the processing method of a workpiece according to the second embodiment.

### DETAILED DESCRIPTION OF THE PREFERRED EMBODIMENTS

Processing methods of a workpiece according to first and second embodiments of the present invention will be described below with reference to the drawings.

### First Embodiment

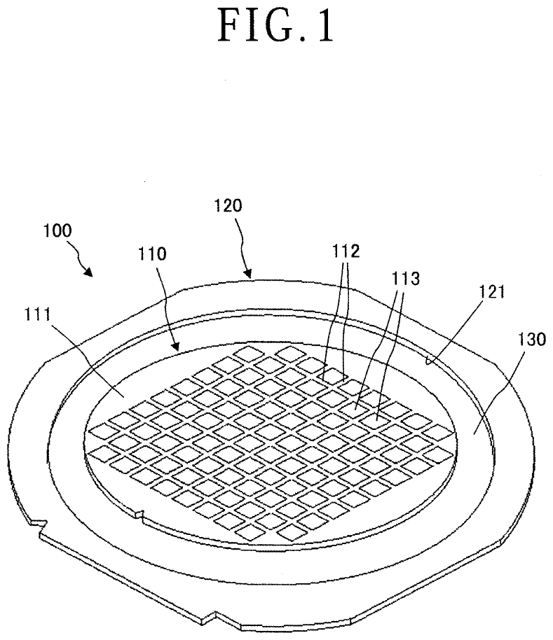

FIG. 1 is a perspective view illustrating a frame unit 100 in a first embodiment. The frame unit 100 illustrated in FIG. 1 includes a wafer 110 that is one example of a workpiece, an annular frame 120, and an adhesive tape 130 that is one example of a support component.

The wafer 110 has a circular disc shape and chips 113 that are devices such as an integrated circuit (IC) are formed on a front surface 111 of a substrate composed of a material such as silicon (Si), for example. These chips 113 are marked out by planned dividing lines 112 formed in a lattice manner.

The wafer 110 is supported in a circular opening 121 of the annular frame 120 by the adhesive tape 130 stuck to a bottom surface of the annular frame 120. In other words, the workpiece including the wafer 110 as one example is supported in the opening 121 of the annular frame 120 through the support component including the adhesive tape 130 as one example. For example, it is preferable for the adhesive tape 130 to include a base layer having flexibility and non-adhesiveness and an adhesive layer that is stacked on this base layer and has flexibility and adhesiveness. However, the support component including the adhesive tape 130 as one example may be a sheet that does not include an adhesive layer and is composed of a thermoplastic resin, or the like. As this sheet, a polyolefin-based sheet, polyethylene sheet, polypropylene sheet, polystyrene sheet, or the like is preferable. It is preferable for this sheet to be stuck to the annular frame 120 and the wafer 110 by thermocompression bonding. Further, the support component does not need to have a sheet shape originally. A powder or liquid may be supplied to one surface of the wafer 110 and be shaped into a sheet shape that covers the one surface of the wafer 110 by thermocompression bonding, pressing, spin-coating, or the like. The material, shape, and so forth of the workpiece and the support component can be decided as appropriate.

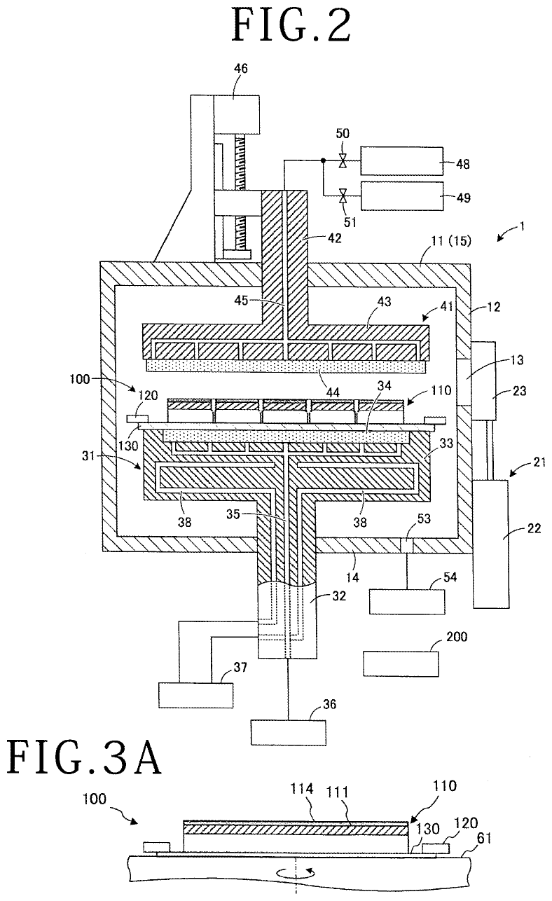

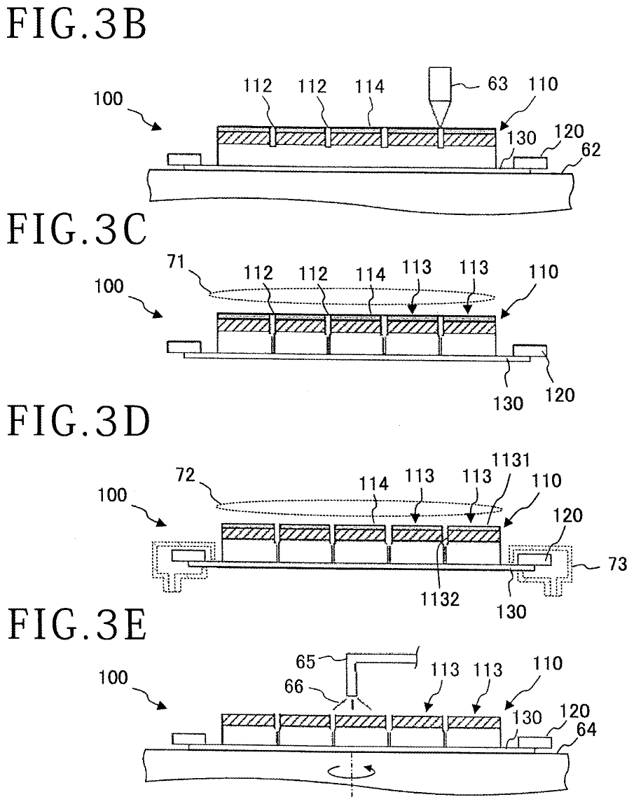

FIG. 2 is a schematic sectional view illustrating an etching apparatus 1 in the first embodiment. The etching apparatus 1 illustrated in FIG. 2 is used for a dividing step (see FIG. 3C) and a hydrophilization step (see FIG. 3D) that will be described later. As illustrated in FIG. 2, a carrying-in/out port 13 is formed in a sidewall 12 of a chamber 11 of the etching apparatus 1 for carrying-in and carrying-out of the frame unit 100. A shutter mechanism 21 is attached to the outer wall surface of the sidewall 12 to open and close the carrying-in/out port 13. A shutter 23 is coupled to an upper end of a cylinder 22 in the shutter mechanism 21 and the carrying-in/out port 13 is opened and closed through raising and lowering of the shutter 23 along the outer wall surface by the cylinder 22. When the carrying-in/out port 13 is closed by the shutter 23, a sealed space is formed in the chamber 11. Further, in the chamber 11, a lower electrode unit 31 and an upper electrode unit 41 that form an electric field are disposed opposed to each other in a vertical direction.

The lower electrode unit 31 is disposed at the upper end of an electrically-conductive support column part 32 that penetrates a bottom wall 14 of the chamber 11. The lower electrode unit 31 is configured through attaching a circular plate-shaped holding plate 34 formed of a porous material to the upper surface of an electrically-conductive holding table 33. The holding plate 34 is connected to a suction source 36 through a suction path 35 in the holding table 33 and the support column part 32. Further, cooling paths 38 through which cooling water sent out from a cooling part 37 passes are formed in the lower electrode unit 31. At the time of etching, heat generated in the holding table 33 is transmitted to the cooling water and an abnormal temperature rise is suppressed.

The upper electrode unit 41 is disposed at the lower end of an electrically-conductive support column part 42 that penetrates an upper wall 15 of the chamber 11. The upper electrode unit 41 is configured through attaching a circular plate-shaped diffusion plate 44 formed of a porous material to the lower surface of an electrically-conductive ejection table 43 that introduces an etching gas into the chamber 11. The diffusion plate 44 is connected to a first gas source 48 and a second gas source 49 through a flow path 45 made inside the ejection table 43 and the support column part 42.

The first gas source 48 is connected to the flow path 45 through a valve 50 and supplies, for example, a fluorine-based gas such as SF₆, CF₄, C₂F₆, C₂F₄, CHF₃, or C₄F₈. The second gas source 49 is connected to the flow path 45 through a valve 51 and supplies, for example, a gas containing O₂, H₂O, N₂, H₂, or Ar, or the like. The first gas source 48 and the second gas source 49 supply gasses into the chamber 11 through flow paths different from each other.

The upper end side of the support column part 42 protrudes upward from the chamber 11 and is coupled to a raising-lowering drive mechanism 46 of a ball screw system disposed on the upper wall 15 of the chamber 11. Through driving of this raising-lowering drive mechanism 46, the upper electrode unit 41 is made to get further away from or closer to the lower electrode unit 31 and a height of the ejection table 43 is adjusted to a proper position with respect to the wafer 110 over the holding table 33.

Through application of a high-frequency voltage between the lower electrode unit 31 and the upper electrode unit 41, a first gas and a second gas become a plasma state in which ions and radicals exist. In the chamber 11, a discharge port 53 is formed under the holding table 33, and a pressure reducing part 54 is connected to the discharge port 53. Air or an etching gas in the chamber 11 is sucked by the pressure reducing part 54. This causes pressure reduction until the inside of the chamber 11 becomes a negative pressure state.

A controller 200 has a processor (for example, central processing unit (CPU)) that functions as a calculation processing device that controls operation of the respective parts of the etching apparatus 1 and a memory. This memory is, for example, a read only memory (ROM) that is a read-only semiconductor memory in which a predetermined control program is recorded in advance, a random access memory (RAM) that is a semiconductor memory that is used as a storage area for work according to need when the processor executes various control programs and to and from which writing and reading can be executed as needed, or the like. For example, the processor controls operation of the respective parts of the etching apparatus 1 by reading out and executing a predetermined program. The number of controllers 200 is not particularly limited and each of multiple controllers 200 may execute control of operations different from each other.

The above-described etching apparatus 1 is desirable one example and can be changed as appropriate as long as it is what can execute the dividing step and the hydrophilization step to be described later.

FIG. 3A to FIG. 3E are sectional views illustrating the respective steps of the processing method of a workpiece according to the present first embodiment.

First, as illustrated in FIG. 3A, the front surface 111 of the wafer 110 is coated with a protective film 114 in the above-described frame unit 100 (protective film coating step). In this step, for example, in the state in which the frame unit 100 is sucked and held on a holding table 61 of a protective film coating apparatus, the frame unit 100 rotates by rotation of the holding table 61 in which the vertical direction is the rotation center. Further, a water-soluble resin is applied onto the front surface 111 of the wafer 110 while the frame unit 100 rotates. When this water-soluble resin cures, the protective film 114 is formed on the wafer 110. The protective film 114 may be what is composed of a resin other than the water-soluble resin, or the like. However, it is desirable that the protective film 114 be composed of a water-soluble resin such as a product in a “HOGOMAX (registered trademark)” series made by DISCO corporation in terms of easiness of removal in a cleaning step to be described later.

Next, as illustrated in FIG. 3B, the protective film 114 is partly removed along the planned dividing lines 112 (see FIG. 1) (protective film removal step). In this step, for example, the frame unit 100 is conveyed to a chuck table 62 of a laser processing apparatus and is held under suction by the chuck table 62 and clamps. It is preferable for the chuck table 62 to be capable of horizontal movement and rotation in which the vertical direction is the rotation center. A laser irradiation part 63 irradiates the planned dividing lines 112 of the wafer 110 with a laser beam and focuses the laser beam on the planned dividing lines 112. This removes the protective film 114 at parts along the planned dividing lines 112 in the wafer 110. At this time, by the above-described laser beam, not only the protective film 114 but also part of the wafer 110 under it is also removed with a groove shape along the planned dividing lines 112. The partial removal of the protective film 114 may be executed by a blade or the like and is not limited to the above-described method.

Next, as illustrated in FIG. 3C, the wafer 110 is divided into multiple chips 113 along the planned dividing lines 112 by supplying a first gas 71 in a plasma state (dividing step).

In this dividing step, the frame unit 100 is carried in to the chamber 11 of the etching apparatus 1 illustrated in FIG. 2 and is sucked and held by the holding table 33. Then, the shutter 23 is closed and the upper electrode unit 41 is brought closer to the lower electrode unit 31 and the distance between electrodes is adjusted. When pressure reduction treatment is initiated by the pressure reducing part 54 until the pressure in the chamber 11 becomes a negative pressure state, the cooling water is caused to pass through the cooling paths 38 and the holding table 33 is cooled by the cooling water.

In the state in which the pressure in the chamber 11 is set to the negative pressure, the etching apparatus 1 jets the first gas supplied from the first gas source 48 through the flow path 45 from the upper electrode unit 41 toward the wafer 110. By application of a high-frequency voltage between the upper electrode unit 41 and the lower electrode unit 31 in this state, the first gas 71 illustrated in FIG. 3C is supplied to the wafer 110. The divides the wafer 110 into the multiple chips 113 along the planned dividing lines 112, along which the protective film 114 of the wafer 110 has been removed. When the first gas source 48 is supplying the first gas, the valve 50 connected to the first gas source 48 is open and the valve 51 connected to the second gas source 49 is closed.

Next, as illustrated in FIG. 3D, front surfaces 1131 and side surfaces 1132 of the chips 113, the exposed adhesive tape 130, and the annular frame 120 that have been hydrophobized through, for example, adhesion of fluorine and formation of a fluorine resin film due to supply of the above-described first gas 71 in the plasma state are hydrophilized by supply of a second gas 72 in a plasma state (hydrophilization step). Because the protective film 114 is formed on the front surface 111 of the wafer 110, the protective film 114 is hydrophobized through modification of a surface layer of the protective film 114 due to formation of a fluorine-based resin film or the like. On the other hand, regarding a region that is not coated with the protective film 114, such as part of the side surfaces 1132 of the chips 113, this region itself is hydrophobized through modification of a surface layer due to formation of the fluorine-based resin film or the like. The second gas 72 hydrophilizes the respective parts (the front surfaces 1131 and the side surfaces 1132 of the chips 113, the adhesive tape 130, and the annular frame 120) through oxidation of the surface, addition of a polar group (for example, OH group), removal of organic substances on the surface, or the like.

It suffices that the hydrophilization is executed on at least any of the above-described respective parts. In this hydrophilization step, upon completion of the supply of the above-described first gas 71 in the plasma state, the valve 50 connected to the first gas source 48 illustrated in FIG. 2 closes and the valve 51 connected to the second gas source 49 opens. Then, with keeping of the state in which the pressure in the chamber 11 is set to the negative pressure, the etching apparatus 1 jets the second gas supplied from the second gas source 49 through the flow path 45 from the upper electrode unit 41 toward the wafer 110. By application of a high-frequency voltage between the upper electrode unit 41 and the lower electrode unit 31 in this state, the second gas 72 in the plasma state illustrated in FIG. 3D is supplied toward the wafer 110. This causes hydrophilization of the front surfaces 1131 that are the upper surfaces of the chips 113, the side surfaces 1132 around the chips 113, the surface of the adhesive tape 130 (for example, parts along the planned dividing lines 112 and a part between the chip 113 and the annular frame 120), and the annular frame 120 that have been hydrophobized through adhesion of fluorine in the plasma etching by the first gas 71. This hydrophilization is implemented through oxidation, addition of a polar group, removal of organic substances, or the like as described above. In the case of asking with use of oxygen plasma, it can be said that the hydrophilization occurs through vaporization of organic substances to which fluorine is linked into CO₂, COF₂, or the like, for example.

When the annular frame 120 and part of the adhesive tape 130 are covered by a cover 73 (illustrated by dashed lines in FIG. 3D) inside the chamber 11, the part that is not covered by the cover 73 in the adhesive tape 130 is hydrophilized by the second gas 72. It is preferable for the cover 73 to be what has a circular annular shape in plan view to surround the annular frame 120 and is internally filled with an inert gas from the lower side to prevent entry of the first gas 71 (adhesion of fluorine).

When the supply of the second gas 72 is completed, the valve 51 connected to the second gas source 49 closes and the application of the high-frequency voltage to the upper electrode unit 41 and the lower electrode unit 31 is stopped and the supply of high-frequency power is stopped. Further, the jet of the gas from the upper electrode unit 41 is stopped and the upper electrode unit 41 is separated from the lower electrode unit 31. Then, the pressure reduction treatment by the pressure reducing part 54 ends and the passing of the cooling water through the cooling paths 38 stops. Moreover, the shutter 23 is opened and the frame unit 100 is carried out to the outside of the chamber 11.

Next, as illustrated in FIG. 3E, after the hydrophilization step, the protective film 114 (see FIG. 3D) is removed and the frame unit 100 is cleaned by a cleaning liquid 66 (cleaning step). In this cleaning step, for example, the frame unit 100 is conveyed to a holding table 64 of a cleaning apparatus and rotates by rotation of the holding table 64 in which the vertical direction is the rotation center in the state in which the frame unit 100 is sucked and held on the holding table 64. Further, while the frame unit 100 rotates, the cleaning liquid 66 that is, for example, purified water or purified water containing a surfactant is supplied from a cleaning liquid supply nozzle 65 onto the wafer 110. The removes the protective film 114.

In the first embodiment described above, the processing method of a workpiece includes the protective film coating step (see FIG. 3A) of coating the front surface 111 of the wafer 110 with the protective film 114 in the frame unit 100 in which the wafer 110 (one example of the workpiece) is supported in the opening 121 of the annular frame 120 through the adhesive tape 130 (one example of the support component), the protective film removal step (see FIG. 3B) of partly removing the protective film 114 along the planned dividing lines 112, and the dividing step (see FIG. 2 and FIG. 3C) of supplying the first gas 71 in a plasma state to divide the wafer 110 into the multiple chips 113 along the planned dividing lines 112. The processing method of a workpiece includes also the hydrophilization step (see FIG. 2 and FIG. 3D) of supplying the second gas 72 in a plasma state to at least any of the front surfaces 1131 and the side surfaces 1132 of the chips 113, the exposed adhesive tape 130, and the annular frame 120 that have been hydrophobized due to this dividing step to hydrophilize the at least any of the front surfaces 1131 and the side surfaces 1132 of the chips 113, the exposed adhesive tape 130, and the annular frame 120 and the cleaning step (see FIG. 3E) of removing the protective film 114 and cleaning the frame unit 100 by the cleaning liquid 66 after the hydrophilization step.

Incidentally, when the wafer 110 is divided into the multiple chips 113 by the plasma etching with use of the first gas 71, the front surfaces 1131 and the side surfaces 1132 of the chips 113 and the adhesive tape 130 are hydrophobized through coating with fluorine or the like and modification of a surface layer as described above, for example. Even when the front surfaces 1131 and the side surfaces 1132 of the chips 113, the adhesive tape 130, and the annular frame 120 are hydrophobized as above, these hydrophobized parts are hydrophilized by the second gas 72 in the plasma state through oxidation of the surface, addition of a polar group, removal of organic substances on the surface, or the like, for example. Thus, it becomes easy to remove the protective film 114 by the cleaning liquid 66 in the cleaning step executed after the hydrophilization step. Further, hydrophilization is caused also in regions in which the protective film 114 is not formed, and therefore the cleaning by the cleaning liquid 66 is effectively executed. Thus, according to the present first embodiment, it is possible to sufficiently execute the removal of the protective film 114 with which the wafer 110 is coated and the cleaning of the wafer 110, the adhesive tape 130, and the annular frame 120.

Moreover, in the present first embodiment, the protective film 114 is a water-soluble resin. Thus, it becomes easier to remove the protective film 114 by the cleaning liquid 66 in the cleaning step.

### Second Embodiment

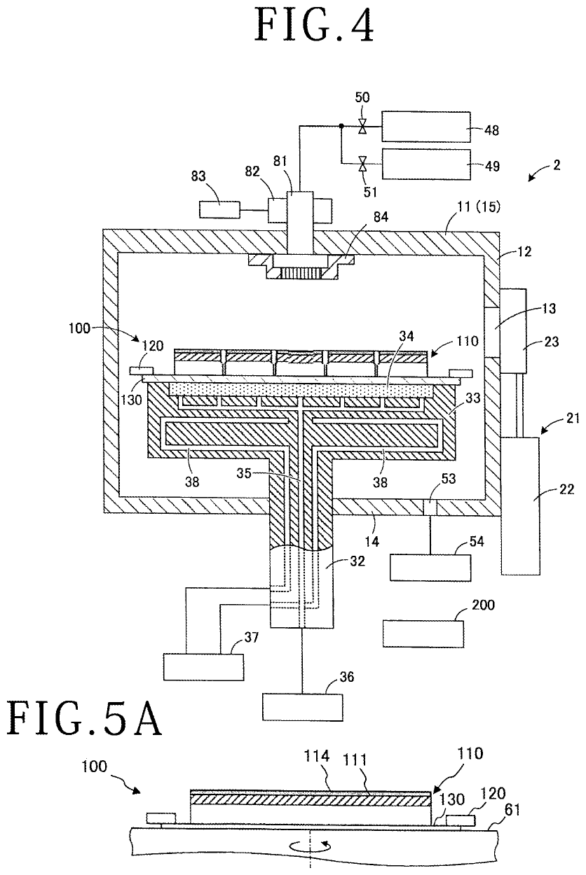

FIG. 4 is a schematic sectional view illustrating an etching apparatus 2 in the second embodiment. The etching apparatus 2 illustrated in FIG. 4 is the etching apparatus 2 of a generally called remote plasma system that turns a gas to plasma outside the chamber 11 differently from the etching apparatus 1 illustrated in the above-described FIG. 2, that is, the etching apparatus 1 of a generally called direct plasma system that turns a gas to plasma inside the chamber 11. Configurations that can be made common with the etching apparatus 1 illustrated in FIG. 2 are given the same numerals in FIG. 4 and description thereof is omitted.

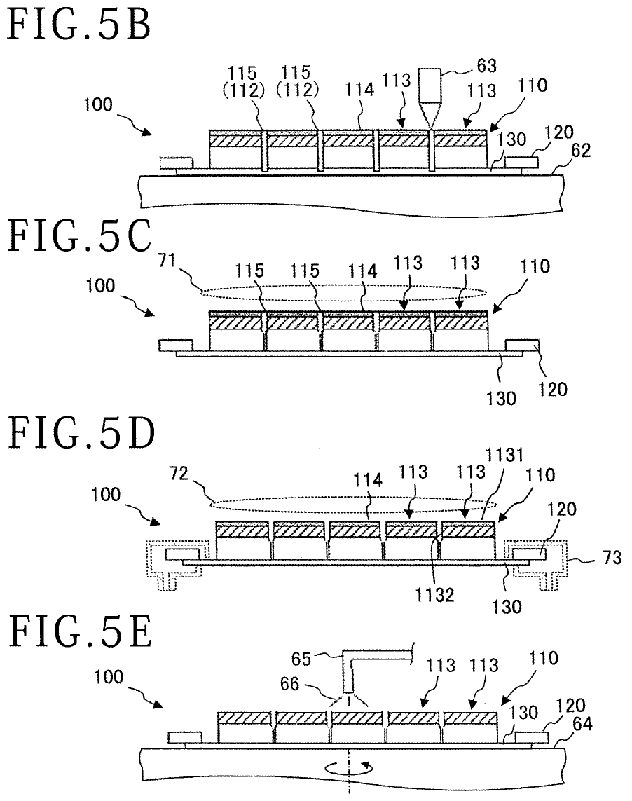

The etching apparatus 2 is used for a plasma etching step (see FIG. 5C) and a hydrophilization step (see FIG. 5D) to be described later. The etching apparatus 2 does not include the upper electrode unit 41, the support column part 42, and the raising-lowering drive mechanism 46 of the etching apparatus 1 illustrated in FIG. 2. Instead, the etching apparatus 2 includes a supply pipe 81, an electrode 82, a high-frequency power supply 83, and a dispersion component 84. Further, the holding table 33 and so forth of the etching apparatus 2 do not function as the lower electrode unit 31 differently from the etching apparatus 1 illustrated in FIG. 2.

As illustrated in FIG. 4, the supply pipe 81 is coupled to the above-described first gas source 48 and second gas source 49 and the upper wall 15 of the chamber 11 of the etching apparatus 2 and supplies a gas to the inside of the chamber 11.

The electrode 82 for applying a high-frequency voltage to the first gas or the second gas that flows in the supply pipe 81 is disposed at a part over the chamber 11 in the supply pipe 81. The high-frequency power supply 83 is connected to the electrode 82. The electrode 82 causes the high-frequency voltage to act on the gas that flows in the supply pipe 81 to change this gas to a plasma state in which ions and radicals exist. The gas in the plasma state is supplied from the supply pipe 81 to the chamber 11.

The dispersion component 84 is attached to the inside of the upper wall 15 of the chamber 11 (that is, side of the space in the chamber 11). It is preferable for the dispersion component 84 to be what disperses the gas in the plasma state supplied from the supply pipe 81 over the frame unit 100 in such a manner as to allow the gas to spread to the whole of the wafer 110.

The above-described etching apparatus 2 is desirable one example and can be changed as appropriate as long as it is what can execute the plasma etching step and the hydrophilization step to be described later.

FIG. 5A to FIG. 5E are sectional views illustrating the respective steps of the processing method of a workpiece according to the present second embodiment.

First, as illustrated in FIG. 5A, the front surface 111 of the wafer 110 is coated with the protective film 114 in the above-described frame unit 100 (protective film coating step). This protective film coating step can be executed similarly to the protective film coating step described with reference to FIG. 3A.

Next, as illustrated in FIG. 5B, processing grooves 115 are formed in the wafer 110 from the front surface 111 of the wafer 110 along the planned dividing lines 112 (see FIG. 1) and the wafer 110 is divided into the multiple chips 113 (processing groove forming step). In this step, for example, the frame unit 100 is conveyed to the chuck table 62 of the laser processing apparatus and is held under suction by the chuck table 62 and clamps. It is preferable for the chuck table 62 to be capable of horizontal movement and rotation in which the vertical direction is the rotation center. The laser irradiation part 63 irradiates the planned dividing lines 112 of the wafer 110 with a laser beam and focuses the laser beam on the planned dividing lines 112. This forms the processing grooves 115 at parts along the planned dividing lines 112 in the wafer 110. The dividing of the chips 113 by the formation of the processing grooves 115 may be executed by cutting with use of a blade or the like, for example, and is not limited to the above-described method.

Next, as illustrated in FIG. 5C, processing strain and processing dust that remain in the processing grooves 115 are removed by supplying the first gas 71 in a plasma state (plasma etching step).

In this plasma etching step, the frame unit 100 is carried in to the chamber 11 of the etching apparatus 2 illustrated in FIG. 4 and is sucked and held by the holding table 33. Then, when the shutter 23 is closed and pressure reduction treatment is initiated by the pressure reducing part 54 until the pressure in the chamber 11 becomes a negative pressure state, the cooling water is caused to pass through the cooling paths 38 and the holding table 33 is cooled by the cooling water.

In the etching apparatus 2, in the state in which the pressure in the chamber 11 is set to the negative pressure, the high-frequency power supply 83 supplies a high-frequency voltage to the electrode 82 to turn a fluorine-based gas supplied from the first gas source 48 through the supply pipe 81 to plasma. The first gas 71 (see FIG. 5C) turned to the plasma is dispersed by the dispersion component 84 and is jetted toward the wafer 110. Plasma etching of the wafer 110 is executed by this jet of the first gas 71. This removes processing strain and processing dust that remain in the processing grooves 115 of the wafer 110. When the first gas source 48 is supplying the fluorine-based gas, the valve 50 connected to the first gas source 48 is open and the valve 51 connected to the second gas source 49 is closed.

Next, as illustrated in FIG. 5D, at least any of the front surfaces 1131 and the side surfaces 1132 of the chips 113, the exposed adhesive tape 130, and the annular frame 120 that have been hydrophobized through, for example, adhesion of fluorine and formation of a fluorine resin film due to the plasma etching step is hydrophilized by the second gas 72 in a plasma state similarly to the above-described first embodiment (hydrophilization step). In this hydrophilization step, upon completion of the above-described plasma etching of the wafer 110, the valve 50 connected to the first gas source 48 illustrated in FIG. 4 closes and the valve 51 connected to the second gas source 49 opens. Then, the high-frequency power supply 83 supplies a high-frequency voltage to the electrode 82 to turn a gas supplied from the second gas source 49 through the supply pipe 81 to plasma. This supplies the second gas 72 illustrated in FIG. 5D toward the wafer 110. Then, at least any of the front surfaces 1131 that are the upper surfaces of the chips 113, the side surfaces 1132 around the chips 113, the surface of the adhesive tape 130 (for example, parts along the planned dividing lines 112 and a part between the chip 113 and the annular frame 120), and the annular frame 120 that have been hydrophobized in the plasma etching is hydrophilized through oxidation of the surface, addition of a polar group, removal of organic substances on the surface, or the like, for example. When the annular frame 120 and part of the adhesive tape 130 are covered by the cover 73 (illustrated by dashed lines in FIG. 5D) inside the chamber 11, the part that is not covered by the cover 73 in the adhesive tape 130 is hydrophilized by the second gas 72.

When the supply of the second gas 72 is completed, the valve 51 connected to the second gas source 49 closes and the application of the high-frequency voltage to the electrode 82 is stopped and the supply of high-frequency power is stopped. Further, the pressure reduction treatment by the pressure reducing part 54 ends and the passing of the cooling water through the cooling paths 38 stops. Moreover, the shutter 23 is opened and the frame unit 100 is carried out to the outside of the chamber 11.

Next, as illustrated in FIG. 5E, after the hydrophilization step, the protective film 114 (see FIG. is removed by the cleaning liquid 66 and the frame unit 100 is cleaned (cleaning step). This cleaning step can be executed similarly to the cleaning step described with reference to FIG. 3E.

In the second embodiment described above, the processing method of a workpiece includes the protective film coating step (see FIG. 5A) of coating the front surface 111 of the wafer 110 with the protective film 114 in the frame unit 100 in which the wafer 110 (one example of the workpiece) is supported in the opening 121 of the annular frame 120 through the adhesive tape 130 (one example of the support component), the processing groove forming step (see FIG. 5B) of forming the processing grooves 115 in the wafer 110 from the front surface 111 along the planned dividing lines 112 to divide the wafer 110 into the multiple chips 113, and the plasma etching step (see FIG. 4 and FIG. 5C) of supplying the first gas 71 in a plasma state to remove processing strain and processing dust that remain in the processing grooves 115. The processing method of a workpiece includes also the hydrophilization step (see FIG. 4 and FIG. 5D) of supplying the second gas 72 in a plasma state to at least any of the front surfaces 1131 and the side surfaces 1132 of the chips 113, the exposed adhesive tape 130, and the annular frame 120 that have been hydrophobized due to this plasma etching step to hydrophilize the at least any of the front surfaces 1131 and the side surfaces 1132 of the chips 113, the exposed adhesive tape 130, and the annular frame 120 and the cleaning step (see FIG. 5E) of removing the protective film 114 and cleaning the frame unit 100 by the cleaning liquid 66 after the hydrophilization step.

Due to this, even when at least any of the front surfaces 1131 and the side surfaces 1132 of the chips 113, the adhesive tape 130, and the annular frame 120 is hydrophobized due to coating thereof with fluorine and modification of a surface layer for example, these hydrophobized parts are hydrophilized by the second gas 72 in the plasma state through oxidation of the surface, addition of a polar group, removal of organic substances on the surface, or the like, for example, similarly to the above-described first embodiment. Thus, it becomes easy to remove the protective film 114 by the cleaning liquid 66 in the cleaning step executed after the hydrophilization step. Further, hydrophilization is caused also in regions in which the protective film 114 is not formed, and therefore the cleaning by the cleaning liquid 66 is effectively executed. Thus, also according to the present second embodiment, it is possible to sufficiently execute the removal of the protective film 114 with which the wafer 110 is coated and the cleaning of the wafer 110, the adhesive tape 130, and the annular frame 120 similarly to the above-described first embodiment.

Moreover, also in the present second embodiment, the protective film 114 is a water-soluble resin. Thus, it becomes easier to remove the protective film 114 by the cleaning liquid 66 in the cleaning step.

It is obvious that the processing method of a workpiece according to the present invention is not limited to the above-described first and second embodiments and may be carried out in various different forms within the range of the technical idea thereof. Further, the respective constituent elements illustrated in the accompanying drawings can be changed as appropriate within a range in which effects of the present invention can be exerted.

As described above, the processing method of a workpiece according to the present invention can sufficiently execute removal of the protective film with which the workpiece is coated and cleaning of the workpiece, the support component that supports the workpiece, and the annular frame by the cleaning liquid. Thus, this processing method is useful in the case of using a wafer as a workpiece processed with use of fluorine-based plasma etching or the like, and so forth.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing method of a workpiece by which the workpiece is processed in a frame unit in which the workpiece is supported in an opening of an annular frame through a support component, the processing method comprising:
a protective film coating step of coating a front surface of the workpiece with a protective film;
a protective film removal step of partly removing the protective film along planned dividing lines;
a dividing step of supplying a first gas in a plasma state to divide the workpiece into a plurality of chips along the planned dividing lines;
a hydrophilization step of supplying a second gas in a plasma state to at least any of front surfaces and side surfaces of the chips, the support component exposed, and the annular frame that have been hydrophobized due to the dividing step to hydrophilize the at least any of the front surfaces and the side surfaces of the chips, the support component exposed, and the annular frame; and
a cleaning step of removing the protective film and cleaning the frame unit by a cleaning liquid after the hydrophilization step.

2. A processing method of a workpiece by which the workpiece is processed in a frame unit in which the workpiece is supported in an opening of an annular frame through a support component, the processing method comprising:
a protective film coating step of coating a front surface of the workpiece with a protective film;
a processing groove forming step of forming processing grooves in the workpiece from a front surface along planned dividing lines to divide the workpiece into a plurality of chips;
a plasma etching step of supplying a first gas in a plasma state to remove processing strain and processing dust that remain in the processing grooves;
a hydrophilization step of supplying a second gas in a plasma state to at least any of front surfaces and side surfaces of the chips, the support component exposed, and the annular frame that have been hydrophobized due to the plasma etching step to hydrophilize the at least any of the front surfaces and the side surfaces of the chips, the support component exposed, and the annular frame; and
a cleaning step of removing the protective film and cleaning the frame unit by a cleaning liquid after the hydrophilization step.

3. The processing method of a workpiece according to claim 1, wherein
the protective film is a water-soluble resin.

4. The processing method of a workpiece according to claim 2, wherein
the protective film is a water-soluble resin.
